(19) United States
(12) Patent Application Publication
(10) Pub. No.: US 2025/0255048 A1
(43) Pub. Date: Aug. 7, 2025

(54) LIGHT-EMITTING DEVICE

(71) Applicant: Lextar Electronics Corporation, Hsinchu City (TW)

(72) Inventors: Yi-Chan YANG, Hsinchu City (TW); Wen-Syun WANG, Hsinchu City (TW); Shiou-Yi KUO, Hsinchu City (TW)

(21) Appl. No.: 19/033,051

(22) Filed: Jan. 21, 2025

(30) Foreign Application Priority Data
Feb. 2, 2024 (TW) 113104163

(51) Int. Cl. H10H 20/841; H10H 20/854

(52) U.S. Cl. CPC H10H 20/841; H10H 20/854

(57) ABSTRACT

A light-emitting device is provided. The light-emitting device includes a substrate, a light-emitting element, a reflective layer, a first encapsulating layer, a wavelength conversion portion, and a second encapsulating layer. The light-emitting element is disposed on the substrate and has a side surface. The reflective layer is disposed on the side surface of the light-emitting element. The first encapsulating layer is disposed on the substrate, wherein the first encapsulating layer surrounds the light-emitting element and the reflective layer. The wavelength conversion portion is disposed on the light-emitting element. The second encapsulating layer is disposed on the first encapsulating layer, wherein the second encapsulating layer surrounds the wavelength conversion portion.

### CROSS REFERENCE TO RELATED APPLICATIONS

This Application claims priority of Taiwan Patent Application No. 113104163, filed on Feb. 2, 2024, the entirety of which is incorporated by reference herein.

### BACKGROUND

### Field of the Disclosure

The present disclosure relates to a light-emitting device, and, in particular, to a light-emitting device including a reflective layer.

### Description of the Related Art

Light-emitting devices include light-emitting elements that may be arranged in various ways. These light-emitting elements may be excited by adjacent light-emitting elements, however, causing a problem with cross-talk between the light-emitting elements. Furthermore, it is difficult to control specific light-emitting elements in the light-emitting device to emit light. In addition, regarding the light-emitting element, there may be a problem wherein the front side of the light-emitting element does not emit enough light, causing insufficient brightness, or the side of the light-emitting element emits too much light, causing light leakage. Moreover, it is difficult to independently control each light-emitting element in the light-emitting device, resulting in all light-emitting elements emitting light at the same time or not emitting light at the same time.

### SUMMARY

The light-emitting device of the present disclosure includes a light-emitting element and a reflective layer disposed on a side surface of the light-emitting element. Therefore, the light-emitting element can emit light from the surface without the reflective layer (for example, the bottom surface 10B of the light-emitting element 10), thereby improving the front luminous amount and/or brightness of the light-emitting device. Furthermore, the reflective layer can reflect the light emitted from the side surface of the light-emitting element (for example, the side surface 10S of the light-emitting element 10), thereby preventing the light from leaking from the side surface of the light-emitting element or avoiding cross-talk between the light-emitting elements. In addition, by adjusting the electrical connection relationship between the circuit board and the light-emitting element, the light-emitting element in the light-emitting device can be independently controlled.

In some embodiments, a light-emitting device is provided. The light-emitting device includes a substrate, a light-emitting element, a reflective layer, a first encapsulating layer, a wavelength conversion portion, and a second encapsulating layer. The light-emitting element is disposed on the substrate and has a side surface. The reflective layer is disposed on the side surface of the light-emitting element. The first encapsulating layer is disposed on the substrate, wherein the first encapsulating layer surrounds the light-emitting element and the reflective layer. The wavelength conversion portion is disposed on the light-emitting element. The second encapsulating layer is disposed on the first encapsulating layer, wherein the second encapsulating layer surrounds the wavelength conversion portion.

The light-emitting device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIGS. 1 to 7 show schematic cross-sectional views of various stages of the manufacturing method of the light-emitting device of the present disclosure according to some embodiments, respectively.

FIGS. 8 and 9 show schematic cross-sectional views of various stages of the manufacturing method of the light-emitting device of the present disclosure according to some embodiments, respectively.

FIG. 10 shows a three-dimensional exploded view of the light-emitting device of the present disclosure according to some embodiments.

FIG. 11 shows a partial top view of a circuit board and a substrate of the present disclosure according to some embodiments.

FIG. 12 shows a partial top view of a circuit board of the present disclosure according to some embodiments.

FIG. 13 shows a top view of a circuit board of the present disclosure according to some embodiments.

FIGS. 14 to 16 show schematic cross-sectional views of various stages of the manufacturing method of the light-emitting device of the present disclosure according to some embodiments, respectively.

FIGS. 17 to 19 show schematic cross-sectional views of various stages of the manufacturing method of the light-emitting device of the present disclosure according to some embodiments, respectively.

FIGS. 20 to 22 show schematic cross-sectional views of various stages of the manufacturing method of the light-emitting device of the present disclosure according to some embodiments, respectively.

FIG. 23 shows a schematic cross-sectional view of a stage of the manufacturing method of the light-emitting device of the present disclosure according to some embodiments.

FIG. 24 shows a schematic cross-sectional view of a stage of the manufacturing method of the light-emitting device of the present disclosure according to some embodiments.

FIGS. 25 and 26 show schematic cross-sectional views of various stages of the manufacturing method of the light-emitting device of the present disclosure according to some embodiments, respectively.

FIG. 27 shows a schematic cross-sectional view of the light-emitting device of the present disclosure according to some embodiments.

FIG. 28 shows a schematic cross-sectional view of the light-emitting device of the present disclosure according to some embodiments.

FIG. 29 shows a schematic diagram of an optical path of a portion of a comparative example of the light-emitting device of the present disclosure.

FIG. 30 shows a schematic diagram of an optical path of a portion of the light-emitting device of the present disclosure.

FIG. 31 shows a schematic diagram of an optical path of a portion of the light-emitting device of the present disclosure.

### DETAILED DESCRIPTION

Light-emitting devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis direction may be a first direction (width direction) D1, the Y-axis direction may be a second direction (length direction) D2, the Z-axis direction may be a third direction (thickness/height direction) D3. In some embodiments, the schematic cross-sectional views of the present disclosure are schematic cross-sectional views observing the XZ plane. In some embodiments, the third direction D3 may be a normal direction of the substrate. In some embodiments, the third direction D3 may be a front direction of the light-emitting device.

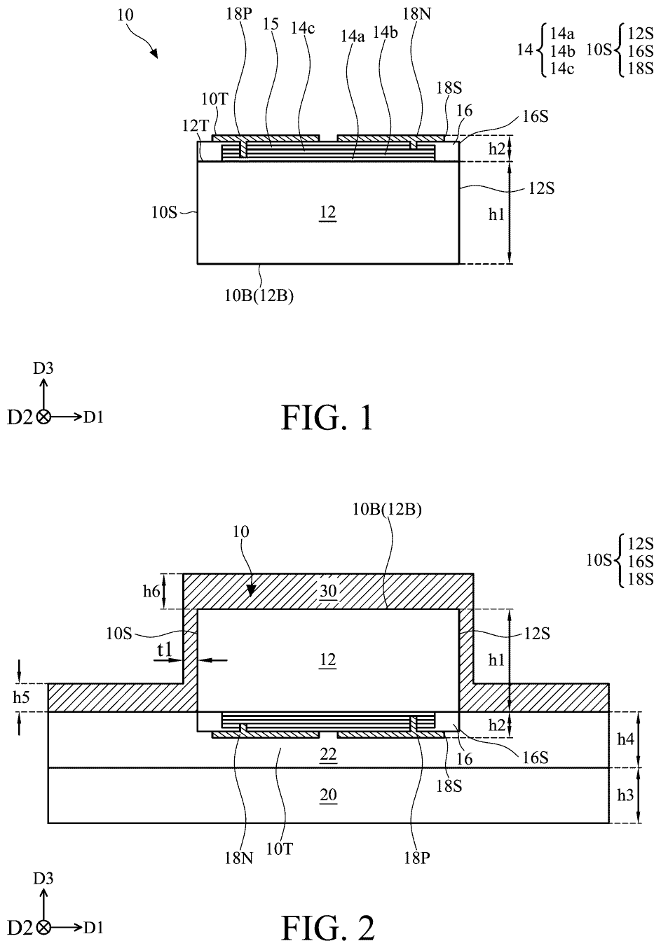

Referring to FIG. 1, it is a schematic cross-sectional view showing various stages of the manufacturing method of the light-emitting device 1 of the present disclosure according to some embodiments. In some embodiments, a light-emitting element 10 is provided. In some embodiments, the light-emitting element 10 may have a top surface 10T, a bottom surface 10B, and a side surface 10S. In some embodiments, in the third direction D3, the bottom surface 10B of the light-emitting element 10 may be opposite to the top surface 10T of the light-emitting element 10. In some embodiments, the side surface 10S may connect the top surface 10T and the bottom surface 10B. In some embodiments, the light-emitting element 10 may have a plurality of side surfaces 10S. For example, the light-emitting element 10 may have 3, 4, 5, 6, 7, 8, or more side surfaces 10S, but the present disclosure is not limited thereto. In some embodiments, the light-emitting element 10 may be a light-emitting diode (LED), a mini light-emitting diode (mini LED), a micro light-emitting diode (micro LED), the like, or a combination thereof, but the present disclosure is not limited thereto. In some embodiments, the light-emitting element 10 may emit a blue light, an ultraviolet light (UV light), or another light with suitable wavelengths.

In some embodiments, the light-emitting element 10 may include a base layer 12, semiconductor stacked layers 14, a reflective film 15, an insulating layer 16, a first contact pad 18P, and a second contact pad 18N.

In some embodiments, the base layer 12 may have a top surface 12T, a bottom surface 12B, and a side surface 12S. In some embodiments, in the third direction D3, the bottom surface 12B of the base layer 12 may be opposite to the top surface 12T of the base layer 12. In some embodiments, the side surface 12S may connect the top surface 12T and the bottom surface 12B. In some embodiments, the base layer 12 may have a plurality of side surfaces 12S. For example, the base layer 12 may have 3, 4, 5, 6, 7, 8, or more side surfaces 12S, but the present disclosure is not limited thereto. In some embodiments, the base layer 12 may include silicon, glass, sapphire, ceramic, another suitable base layer, or a combination thereof, but the present disclosure is not limited thereto. In some embodiments, the base layer 12 may include polyimide (PI), polycarbonate (PC), polyethylene terephthalate (PET), polypropylene (PP), another suitable base layer, or a combination thereof, but the present disclosure is not limited thereto. For example, the base layer 12 may include sapphire. In some embodiments, a roughness of the bottom surface 12B of the base layer 12 is less than a roughness of the side surface 12S of the base layer 12.

In some embodiments, the base layer 12 may have a first height h1 in the third direction D3. In some embodiments, the first height h1 may be greater than or equal to 50 um and less than or equal to 250 um. For example, the first height h1 may be 50 um, 100 um, 110 um, 120 um, 130 um, 140 um, 150 um, 160 um, 170 um, 180 um, 190 um, 200 um, 250 um, or any value or any range of values between the aforementioned values, but the present disclosure is not limited thereto.

In some embodiments, the semiconductor stacked layers 14 may be disposed on the top surface 12T of the base layer 12. In some embodiments, the semiconductor stacked layers 14 may include a first semiconductor layer 14a, a light-emitting layer 14b, and a second semiconductor layer 14c. The first semiconductor layer 14a may be disposed on the base layer 12, the light-emitting layer 14b may be disposed on the first semiconductor layer 14a, and the second semiconductor layer 14c may be disposed on the light-emitting layer 14b. In some embodiments, the first semiconductor layer 14a, the light-emitting layer 14b, and the second semiconductor layer 14c may be formed by an epitaxial growth process, but the present disclosure is not limited thereto. In some embodiments, the first semiconductor layer 14a may be a P-type semiconductor layer, and the second semiconductor layer 14c may be an N-type semiconductor layer. In other embodiments, the conductivity types of the first semiconductor layer 14a and the second semiconductor layer 14c may be the reverse.

In some embodiments, the P-type semiconductor layer may include an II-VI group material or a III-V group material. For example, the II-VI group material may include zinc selenide (ZnSe). For example, the III-V group material may include gallium nitride (GaN), aluminum nitride (AlN), indium nitride (InN), indium gallium nitride (InGaN), aluminum gallium nitride (AlGaN), aluminum indium gallium nitride (AlInGaN), the like, or a combination thereof, but the present disclosure is not limited thereto. In some embodiments, the P-type semiconductor layer may include a dopant such as magnesium (Mg) or carbon (C), but the present disclosure is not limited thereto. In some embodiments, the light-emitting layer 14b may include intrinsic semiconductor material. For example, the intrinsic semiconductor material may include indium gallium nitride (InGaN), gallium nitride (GaN), aluminum gallium nitride (AlGaN), or aluminum indium gallium nitride (AlInGaN), the like, or a combination thereof, but the present disclosure is not limited thereto. In some embodiments, the light-emitting layer 14b may include quantum well (QW) or multiple quantum well (MQW). In some embodiments, the N-type semiconductor layer may include an II-VI group material or a III-V group material. In some embodiments, the N-type semiconductor layer may include a dopant such as silicon (Si) or germanium (Ge), but the present disclosure is not limited thereto.

In some embodiments, the reflective film 15 may be disposed on the semiconductor stacked layers 14. In some embodiments, the reflective film 15 may include a reflective material. For example, the reflective material may include silver (Ag), aluminum (Al), copper (Cu), chromium (Cr), titanium (Ti), the like, or a combination thereof, but the present disclosure is not limited thereto. In some embodiments, the insulating layer 16 may be disposed on the side surface of the semiconductor stacked layers 14, the top and side surfaces of the reflective film 15, and the top surface 12T of the base layer 12. In some embodiments, the reflective film 15 may be formed by electroplating, chemical vapor deposition, sputtering, resistance heating evaporation, electron beam evaporation, another suitable formation process, or a combination thereof.

In some embodiments, the first contact pad 18P and the second contact pad 18N may be disposed on the insulating layer 16. In some embodiments, the first contact pad 18P and the second contact pad 18N may pass through the insulating layer 16 and may be electrically connected to the semiconductor stacked layers 14. The first contact pad 18P may be electrically connected to the first semiconductor layer 14a, and the second contact pad 18N may be electrically connected to the second semiconductor layer 14c. In some embodiments, the first contact pad 18P and the second contact pad 18N may include a conductive material. For example, the conductive material may include a metal, a metal nitride, a semiconductor material, another suitable conductive material, or a combination thereof, but the present disclosure is not limited thereto. In some embodiments, the conductive material may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), alloy or compound thereof, any other suitable conductive material, or a combination thereof, but the present disclosure is not limited thereto. In some embodiments, the conductive material may include transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material, or a combination thereof, but the present disclosure is not limited thereto. In some embodiments, the first contact pad 18P and the second contact pad 18N may be formed by electroplating, chemical vapor deposition, sputtering, resistance heating evaporation, electron beam evaporation, atomic layer deposition (ALD), another suitable formation process, or a combination thereof.

In some embodiments, there may be a second height h2 between the top surface 12T of the base layer 12 and the top surface 10T of the light-emitting element 10 in the third direction D3. In some embodiments, the second height h2 may be greater than or equal to 1 um and less than or equal to 50 um. For example, the second height h2 may be 1 um, 5 um, 10 um, 15 um, 20 um, 25 um, 30 um, 35 um, 40 um, 45 um, 50 um, or any value or any range of values between the aforementioned values, but the present disclosure is not limited thereto.

Referring to FIG. 2, it is a schematic cross-sectional view showing various stages of the manufacturing method of the light-emitting device 1 of the present disclosure according to some embodiments. In some embodiments, as shown in FIG. 2, a carrier board 20 is provided. In some embodiments, the carrier board 20 may include wafer, chip, glass, quartz, sapphire, ceramic, another suitable carrier board, or a combination thereof, but the present disclosure is not limited thereto. In some embodiments, the carrier board 20 may include polyimide (PI), polycarbonate (PC), polyethylene terephthalate (PET), polypropylene (PP), temporary carrier board, another suitable carrier board, or a combination thereof, but the present disclosure is not limited thereto. For example, the carrier board 20 may be a heat-resistant PET carrier board. In some embodiments, the carrier board 20 may have a third height h3 in the third direction D3. In some embodiments, the third height h3 may be greater than or equal to 30 um and less than or equal to 100 um. For example, the third height h3 may be 30 um, 40 um, 50 um, 60 um, 70 um, 80 um, 90 um, 100 um, or any value or any range of values between the aforementioned values, but the present disclosure is not limited thereto.

In some embodiments, as shown in FIG. 2, the light-emitting element 10 may be bonded on the carrier board 20. For ease of explanation, FIG. 2 shows one light-emitting element 10 bonded on the carrier board 20, but the present disclosure is not limited thereto. In other embodiments, a plurality of light-emitting elements 10 may be bonded on the carrier board 20.

In some embodiments, a first adhesive layer 22 may be formed on the carrier board 20 so as to bond the light-emitting element 10 to the carrier board 20 by the first adhesive layer 22. In some embodiments, the top surface 10T of the light-emitting element 10 may be closer to the carrier board 20 than the bottom surface 10B of the light-emitting element 10. In some embodiments, the first contact pad 18P and the second contact pad 18N face the carrier board 20. In some embodiments, the insulating layer 16, the first contact pad 18P, and the second contact pad 18N of the light-emitting element 10 may be buried in the first adhesive layer 22, and the bottom surface 12B and side surface 12S of the base layer 12 of the light-emitting element 10 may be exposed.

In some embodiments, the first adhesive layer 22 may serve as a separation layer or a release layer. In some embodiments, the first adhesive layer 22 may include thermal release glue, ultraviolet (UV) release glue, light-to-heat conversion (LTHC) glue, another suitable release type adhesive material, or a combination thereof, but the present disclosure is not limited thereto. In some embodiments, the first adhesive layer 22 may be formed by a coating process or some other suitable formation process, or a combination thereof, but the present disclosure is not limited thereto. In some embodiments, the first adhesive layer 22 may have a fourth height h4 in the third direction D3. In some embodiments, the fourth height h4 may be greater than or equal to 20 um and less than or equal to 80 um. For example, the fourth height h4 may be 20 um, 30 um, 40 um, 50 um, 60 um, 70 um, 80 um, or any value or any range of values between the aforementioned values, but the present disclosure is not limited thereto.

In some embodiments, as shown in FIG. 2, a reflective layer 30 may be formed on the side surface 10S and the bottom surface 10B of the light-emitting element 10. In some embodiments, the adhesive layer 24 may be formed on the side surface 12S of the base layer 12 and the bottom surface 12B of the base layer 12 (as shown in FIG. 20). In some embodiments, the reflective layer 30 may be formed by electroplating, chemical vapor deposition, sputtering, resistance heating evaporation, electron beam evaporation, another suitable formation process, or a combination thereof, but the present disclosure is not limited thereto. In some embodiments, the reflective layer 30 may be blanketly formed. In some embodiments, in the third direction D3, the reflective layer 30 on the carrier board 20 may have a fifth height h5, and the reflective layer 30 on the bottom surface 10B of the light-emitting element 10 may have a sixth height h6. In some embodiments, the fifth height h5 and the sixth height h6 may be greater than or equal to 10 um and less than or equal to 80 um. For example, the fifth height h5 and the sixth height h6 may be respectively 20 um, 30 um, 40 um, 50 um, 60 um, 70 um, 80 um, or any value or any range of values between the aforementioned values, but the present disclosure is not limited thereto. In some embodiments, in the first direction D1, the reflective layer 30 on the side surface 10S of the light-emitting element 10 may have a thickness t1. In some embodiments, the thickness t1 may be greater than or equal to 0.2 um and less than or equal to 10 um. For example, the thickness t1 may be 0.2 um, 0.3 um, 0.4 um, 0.5 um, 1 um, 2 um, 3 um, 4 um, 5 um, 6 um, 7 um, 8 um, 9 um, 10 um, or any value or any range of values between the aforementioned values, but the present disclosure is not limited thereto. For example, the thickness t1 may be 0.2 um˜0.5 um. When the thickness t1 of the reflective layer 30 is too thin, it is difficult to effectively reflect the light emitted from the light-emitting element 10. When the thickness t1 of the reflective layer 30 is too thick, the volume of the reflective layer 30 will be too large.

In some embodiments, the reflective layer 30 may include a reflective material. For example, the reflective material may include silver (Ag), aluminum (Al), copper (Cu), chromium (Cr), titanium (Ti), alloys thereof, the like, or a combination thereof, but the present disclosure is not limited thereto. In some embodiments, the reflective layer 30 may include aluminum (Al), or the reflective layer 30 may be aluminum (Al) and substantially exclude copper (Cu). In some embodiments, the reflective layer 30 may include aluminum- copper alloy (AlCu), and the weight of copper in the aluminum-copper alloy accounts for 0.1% to 20% of the total weight of the aluminum-copper alloy. In some embodiments, the aluminum-copper alloy may include 0.1% to 20% copper and 80% to 99.9% aluminum based on the total weight of the aluminum-copper alloy. For example, the weight of copper in the aluminum-copper alloy accounts for 0.1%, 0.5%, 1%, 2%, 3%, 4%, 5%, 10%, 15%, 20%, or any value or any range of values between the aforementioned values, but the present disclosure is not limited thereto. For example, the weight of copper in the aluminum-copper alloy accounts for 0.1% to 0.5% of the total weight of the aluminum-copper alloy. When the weight of copper is too high, the reflectivity of the aluminum-copper alloy is insufficient. In other embodiments, the reflective layer 30 may include aluminum-copper alloy (AlCu), and the atoms number of copper in the aluminum-copper alloy accounts for 0.1% to 20% of the total atoms number of the aluminum-copper alloy; or the mass of copper accounts for 0.1% to 20% of the total mass of the aluminum-copper alloy; or the volume of copper in the aluminum-copper alloy accounts for 0.1% to 20% of the total volume of the aluminum-copper alloy.

In some embodiments, the reflective layer 30 may include a distributed Bragg reflection (DBR). In some embodiments, the distributed Bragg reflection may be formed on the side surface 12S of the base layer 12 by the atomic layer deposition (ALD). Accordingly, the reflective layer 30 may improve the luminous efficiency of the light-emitting element 10.

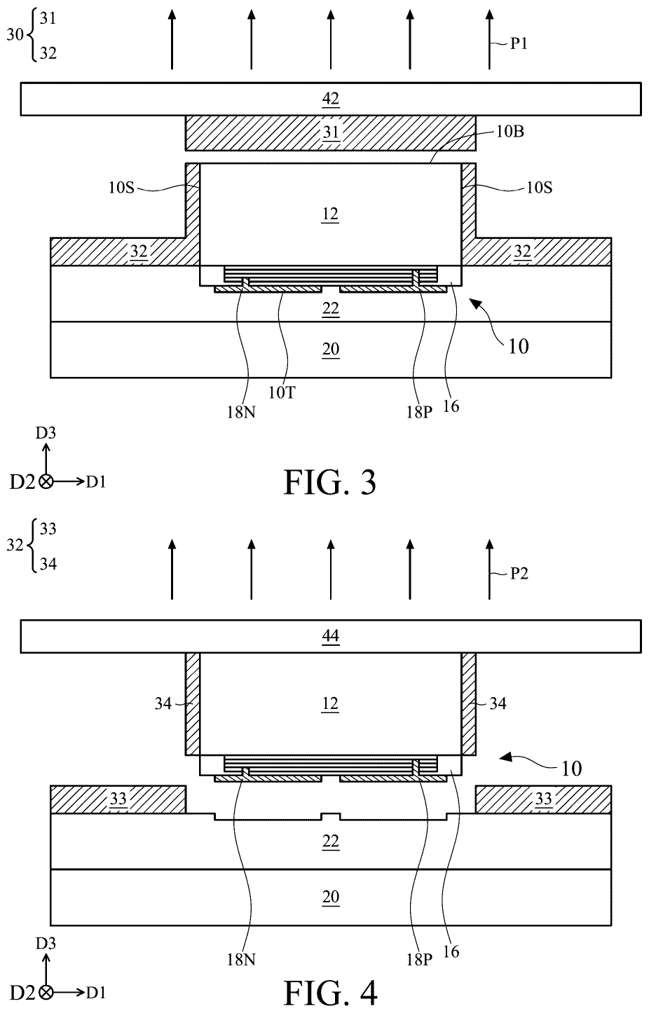

Referring to FIG. 3, it is a schematic cross-sectional view showing various stages of the manufacturing method of the light-emitting device 1 of the present disclosure according to some embodiments. In some embodiments, as shown in FIG. 3, a first removal process PI may be performed to remove a first portion 31 of the reflective layer 30 so as to form the reflective layer 32. In some embodiments, a second adhesive layer 42 may be formed on the reflective layer 30 so that the reflective layer 30 is located between the light-emitting element 10 and the second adhesive layer 42. Then, the second adhesive layer 42 may be separated to remove the second adhesive layer 42 and the first portion 31 of the reflective layer 30, thereby exposing the bottom surface 10B of the light-emitting element 10, that is, exposing the bottom surface 12B of the base layer 12. In some embodiments, the light-emitting element 10 may be located between the first adhesive layer 22 and the second adhesive layer 42. In some embodiments, the material and formation method of the second adhesive layer 42 may be the same as or different from the material and formation method of the first adhesive layer 22. In some embodiments, the viscosity of the second adhesive layer 42 may be less than the viscosity of the first adhesive layer 22. Therefore, during the first removal process P1, the light-emitting element 10 is still bonded on the carrier board 20 by the first adhesive layer 22 without being separated from the carrier board 20. In some embodiments, the first portion 31 may be a portion of the reflective layer 30 located on the bottom surface 10B of the light-emitting element 10.

Referring to FIG. 4, it is a schematic cross-sectional view showing various stages of the manufacturing method of the light-emitting device 1 of the present disclosure according to some embodiments. In some embodiments, as shown in FIG. 4, a second removal process P2 may be performed to remove a second portion 33 of the reflective layer 32 so that a reflective layer 34 may be formed on the side surface 12S of the base layer 12. In some embodiments, a third adhesive layer 44 may be formed on the exposed bottom surface 10B of the light-emitting element 10 so that the light-emitting element 10 is located between the third adhesive layer 44 and the first adhesive layer 22. Then, the first adhesive layer 22 may be separated by, for example, irradiating UV light to remove the first adhesive layer 22 and the second portion 33 of the reflective layer 30 so as to expose the top surface 10T of the light-emitting element 10. In some embodiments, the third adhesive layer 44 may be directly disposed on the exposed bottom surface 10B of the light-emitting element 10. In some embodiments, the material and formation method of the third adhesive layer 44 may be the same as or different from the material and formation method of the first adhesive layer 22. In some embodiments, the viscosity of the third adhesive layer 44 may be greater than the viscosity of the first adhesive layer 22. Therefore, during the second removal process P2, the light-emitting element 10 is bonded to the third adhesive layer 44 and separated from the first adhesive layer 22 and the carrier board 20. In some embodiments, the second portion 33 may be a portion of the reflective layer 32 located on the first adhesive layer 22.

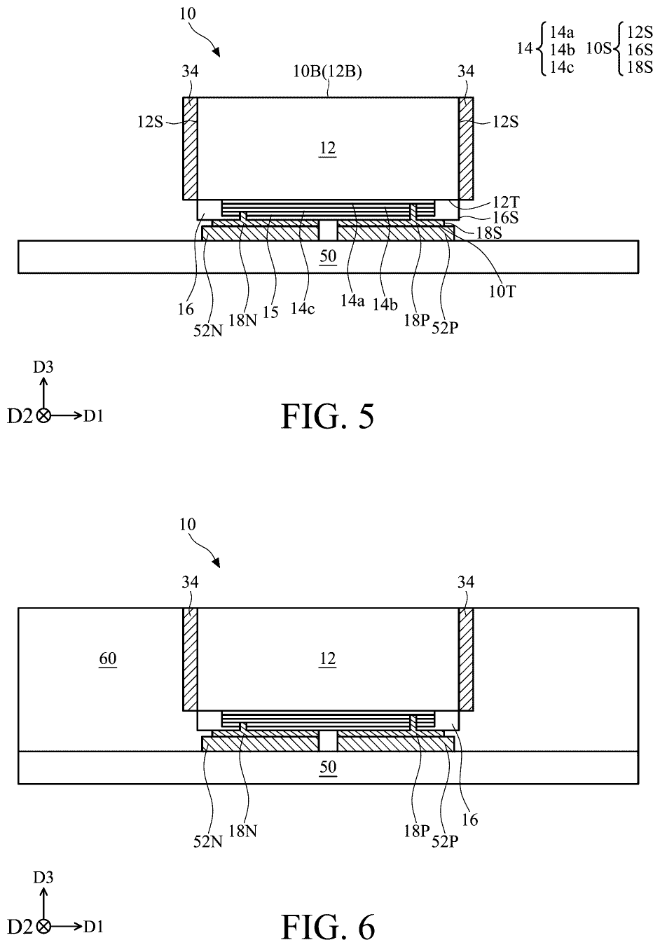

Referring FIG. 5, it is a schematic cross-sectional view showing various stages of the manufacturing method of the light-emitting device 1 of the present disclosure is shown according to some embodiments. In some embodiments, as shown in FIG. 5, the light-emitting element 10 may be transferred to the substrate 50, and the third adhesive layer 44 may be separated by, for example, irradiating UV light. In some embodiments, the plurality of light-emitting elements 10 may be transferred to the substrate 50 by, for example, a mass transfer process. In some embodiments, the substrate 50 may include a substrate having a circuit. In some embodiments, the substrate 50 may include silicon, glass, sapphire, ceramic, another suitable substrate, or a combination thereof, but the present disclosure is not limited thereto. In some embodiments, the substrate 50 may include polyimide (PI), polycarbonate (PC), polyethylene terephthalate (PET), polypropylene (PP), another suitable substrate, or a combination thereof, but the present disclosure is not limited thereto. For example, the substrate 50 may include a substrate for an adaptive driving beam (ADB). In some embodiments, the substrate 50 may include a ceramic substrate for an adaptive driving beam (ADB).

In some embodiments, the substrate 50 may include a third contact pad 52P and a fourth contact pad 52N so that other components are electrically connected to the substrate 50 by the third contact pad 52P and the fourth contact pad 52N. In some embodiments, the materials and formation methods of the third contact pad 52P and the fourth contact pad 52N may be the same as or different from the materials and formation methods of the first contact pad 18P and the second contact pad 18N. In some embodiments, as shown in FIG. 5, the first contact pad 18P may be electrically connected to the third contact pad 52P, and the second contact pad 18N may be electrically connected to the fourth contact pad 52N.

In some embodiments, as shown in FIG. 5, the reflective layer 34 may cover at least a portion of the side surface 10S of the light-emitting element 10. In some embodiments, the reflective layer 34 may cover the side surface 12S of the base layer 12 of the light-emitting element 10. In some embodiments, the reflective layer 34 may expose the top surface 10T and the bottom surface 10B of the light-emitting element 10. In some embodiments, the reflective layer 34 only covers the side surface 12S of the base layer 12 of the light-emitting element 10. In some embodiments, as shown in FIG. 2, since the insulating layer 16, the first contact pad 18P, and the second contact pad 18N of the light-emitting element 10 may be buried in the first adhesive layer 22, therefore, as shown in FIG. 4, when the first adhesive layer 22 is removed, the reflective layer 34 may expose the insulating layer 16, the first contact pad 18P, and the second contact pad 18N. In other words, the reflective layer 34 may expose the side surface 16S of the insulating layer 16 and the side surfaces 18S of the first contact pad 18P and the second contact pad 18N.

Accordingly, the light emitted by the light-emitting element 10 may be emitted from the bottom surface 10B of the light-emitting element 10 where the reflective layer 34 does not be located thereon, thereby improving the luminous efficiency of the light-emitting element 10. Therefore, the front luminous amount and/or brightness of the light-emitting device may be improved. Furthermore, the light emitted from the side surface 10S of the light-emitting element 10 may be reflected by the reflective layer 34 and directed to the bottom surface 10B of the light-emitting element 10 where the reflective layer 34 does not be located thereon to emit light, thereby improving the front luminous amount and/or brightness of the light-emitting device. In addition, the reflective layer 34 may prevent the light emitted by the light-emitting element 10 from leaking from the side surface 10S. In addition, the reflective layer 34 may prevent the light emitted by one light-emitting element 10 from interfering with another light-emitting element so as to prevent cross-talk between the light-emitting elements.

Referring to FIG. 6, it is a schematic cross-sectional view showing various stages of the manufacturing method of the light-emitting device 1 of the present disclosure according to some embodiments. In some embodiments, as shown in FIG. 6, a first encapsulating layer 60 may be formed on the substrate 50. In some embodiments, the first encapsulating layer 60 may surround the light-emitting element 10 and the reflective layer 34. In some embodiments, the first encapsulating layer 60 may be disposed on the reflective layer 34, the insulating layer 16, the first contact pad 18P, the second contact pad 18N, the third contact pad 52P, the fourth contact pad 52N, and the substrate 50. In some embodiments, the first encapsulating layer 60 may directly contact the reflective layer 34.

In some embodiments, the first encapsulating layer 60 may include a first (reflective) material. In some embodiments, the first reflective material may include a first matrix and first dispersed particles dispersed in the first matrix. In some embodiments, the first matrix may include transparent adhesive. For example, the first matrix may include silicone, epoxy, B-stage resin, the like, or a combination thereof, but the present disclosure is not limited thereto. In some embodiments, the first dispersed particles may include reflective material or scattering material. For example, the first dispersed particles may include titanium dioxide (TiO₂), silicon oxide (SiOₓ), the like, or a combination thereof, but the present disclosure is not limited thereto. B-stage resin is a two-stage thermosetting adhesive. “B-stage” refers to a reaction between the resin and a curing agent to form a semi-cured solid, which may become a fully cured state after being heated and cured. In some embodiments, the weight of the first dispersed particles accounts for 0.1% to 20% of the total weight of the first reflective material. For example, the weight of the first dispersed particles accounts for 0.1%, 1%, 5%, 10%, 15%, 20%, or any value or any range of values between the aforementioned values of the total weight of the first reflective material, but the present disclosure is not limited thereto. In other words, the first dispersed particles may be 0.1% by weight (wt %)˜20% by weight of the first reflective material. In some embodiments, the particle size of the first dispersed particles may be less than or equal to 1 um. For example, the particle size of the first dispersed particles may be 1 um, 0.9 um, 0.8 um, 0.6 um, 0.5 um, 0.4 um, 0.2 um, 0.1 um, or smaller, but the present disclosure is not limited thereto. For example, the first encapsulating layer 60 may include a light-reflecting material, for example, a white reflective material. Accordingly, the first encapsulating layer 60 may reflect and/or scatter the light emitted by the light-emitting element 10, thereby improving the luminous efficiency of the light-emitting element 10. Therefore, the front luminous amount and/or brightness of the light-emitting device may be increased, and light leakage and/or cross-talk may be avoided.

In the following, for convenience of explanation, it is shown that three light-emitting elements 10 have been transferred on the substrate 50, but the present disclosure is not limited thereto.

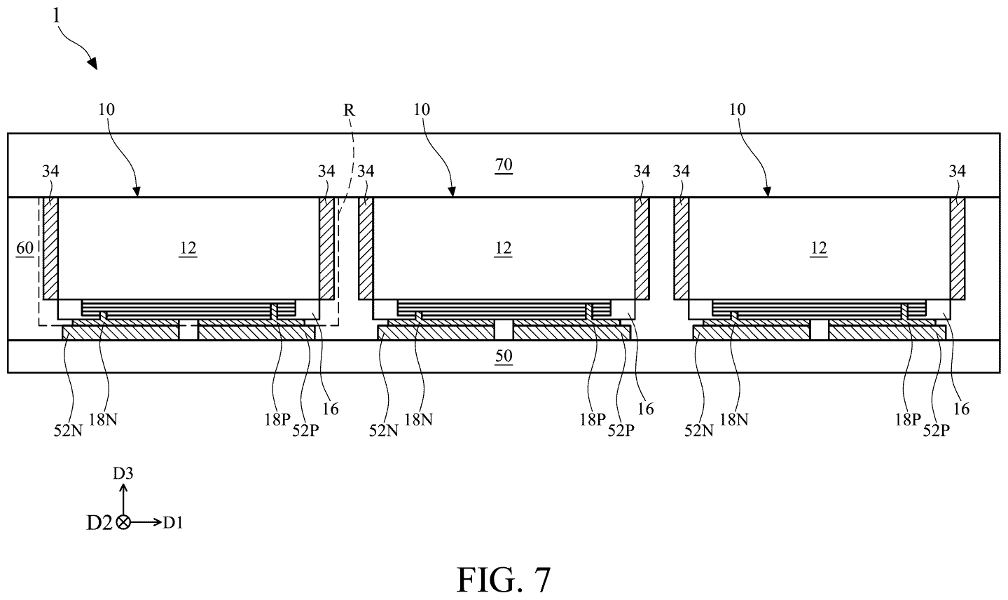

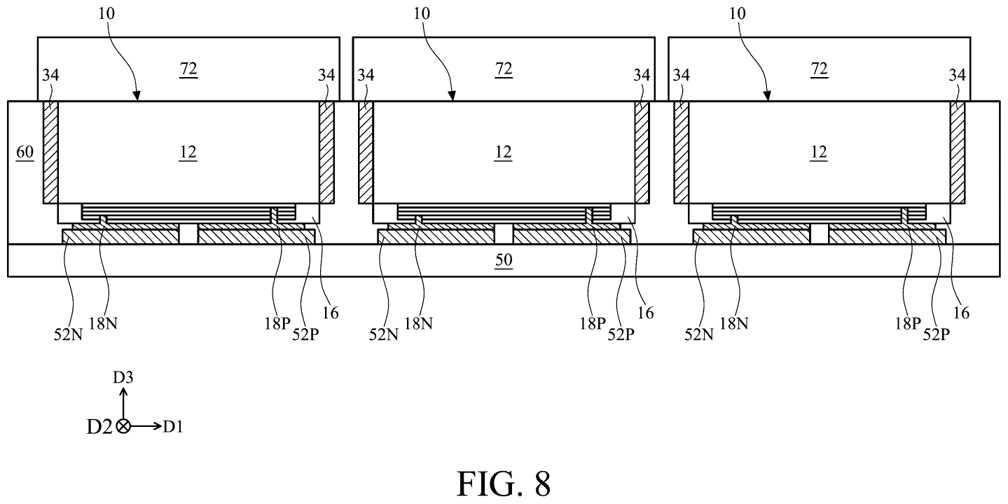

Referring to FIG. 7, it is a schematic cross-sectional view showing various stages of the manufacturing method of the light-emitting device 1 of the present disclosure according to some embodiments. In some embodiments, as shown in FIG. 7, a wavelength conversion layer 70 may be formed on the light-emitting element 10. In some embodiments, the wavelength conversion layer 70 may be phosphor-in-glass (PIG), for example, the phosphors disposed in the glass, to avoid thermal quenching of the fluorescence (phosphor). In some embodiments, the wavelength conversion layer 70 may be phosphors mixed with adhesive such as silicone, and formed into a phosphor sheet. In some embodiments, the wavelength conversion layer 70 converts a portion of the light (for example, the blue light) emitted by the light-emitting element 10 into the yellow light. The light emitted by the light-emitting element 10 that is not absorbed by the wavelength conversion layer 70 (for example, blue light) may be mixed with a light passing through the wavelength conversion layer 70 (for example, the yellow light) into the white light, but the present disclosure is not limited thereto. In some embodiments, an adhesive layer (not shown) disposed between the wavelength conversion layer 70 and the light-emitting element 10 may be further included, so that the wavelength conversion layer 70 and the light-emitting element 10 are bonded by the adhesive layer. For example, the adhesive layer may be transparent silicone resin. Therefore, the light-emitting device 1 may be applied to an adaptive driving beam.

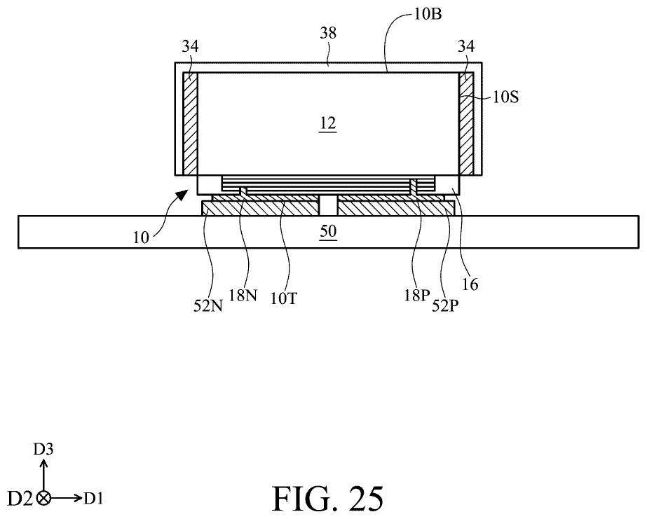

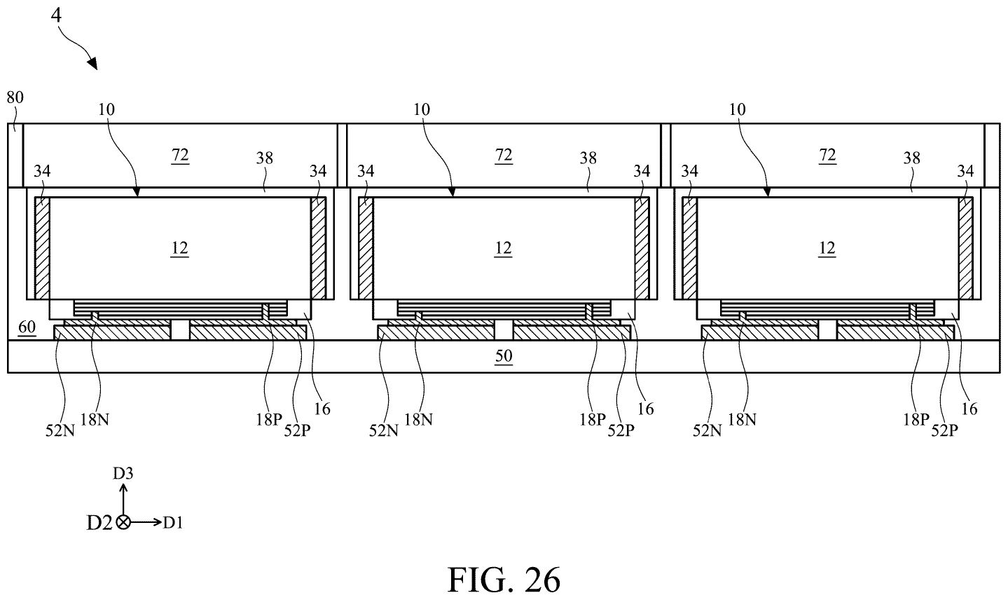

Referring to FIG. 8, it is a schematic cross-sectional view of various stages of the manufacturing method of the light-emitting device 1′ of the present disclosure according to some embodiments. In some embodiments, as shown in FIG. 8, the wavelength conversion layer 70 may be cut to form a plurality of wavelength conversion portions 72 on the light-emitting element 10. In some embodiments, the cutting process may substantially cut to the top surface of the first encapsulating layer 60 while maintaining the integrity of the first encapsulating layer 60. That is to say, the cutting depth of the cutting process may be substantially equal to the height of the wavelength conversion layer 70. In other embodiments, the cutting depth of the cutting process may be less than the height of the wavelength conversion layer 70 (as shown in the subsequent FIG. 25), or the cutting depth of the cutting process may be greater than the height of the wavelength conversion layer 70 (as shown in the subsequent FIG. 26). In some embodiments, the spacing between the plurality of wavelength conversion portions 72 may be less than or equal to 50 um. In some embodiments, each of the plurality of wavelength conversion portions 72 corresponds to each of the plurality of light-emitting elements 10, respectively.

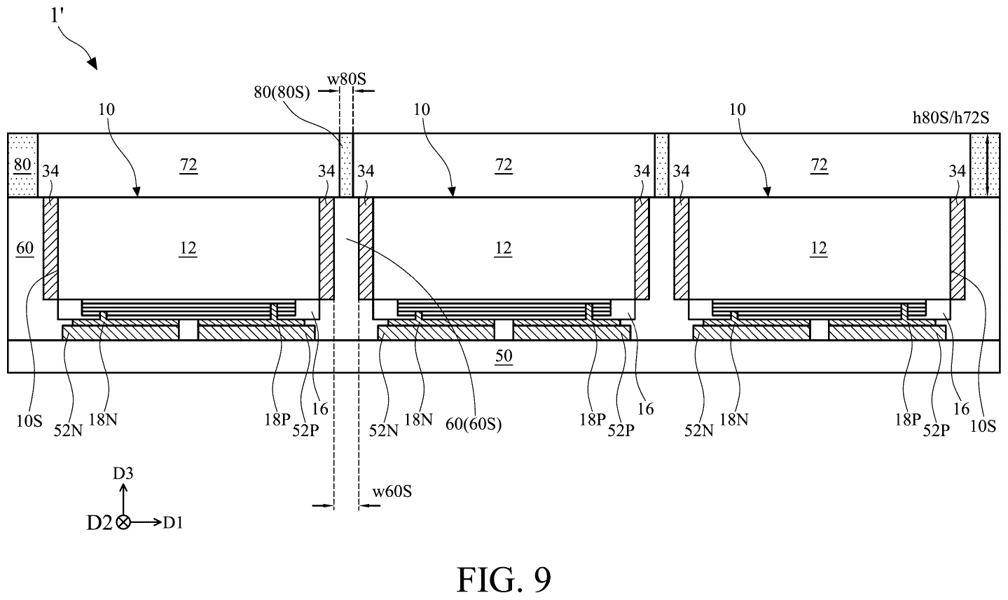

Referring to FIG. 9, it is a schematic cross-sectional view showing various stages of the manufacturing method of the light-emitting device 1′ of the present disclosure according to some embodiments. In some embodiments, as shown in FIG. 9, a second encapsulating layer 80 may be formed on the first encapsulating layer 60 to form the light-emitting device 1′. In some embodiments, the second encapsulating layer 80 may surround the wavelength conversion portion 72. In some embodiments, the second encapsulating layer 80 may include a second (reflective) material. In some embodiments, the second reflective material may include a second matrix and second dispersed particles dispersed in the second matrix. In some embodiments, the second matrix and the first matrix may be the same or different, and the second dispersed particles and the first dispersed particles may be the same or different. For example, the second encapsulating layer 80 may include a light-reflecting material, for example, a white reflective material. Accordingly, the second encapsulating layer 80 may reflect and/or scatter the light emitted by the light-emitting element 10, thereby improving the luminous efficiency of the light-emitting element 10. Therefore, the front luminous amount and/or brightness of the light-emitting device may be increased, and light leakage and/or cross-talk may be avoided. In some embodiments, the second encapsulating layer 80 may include a light-absorbing material. The light-absorbing material includes, for example, black carbon powder, but the present disclosure is not limited thereto. In some embodiments, the second encapsulating layer 80 may be a black adhesive. In some embodiments, the second encapsulating layer 80 is formed by the black adhesive, wherein the black adhesive is formed by uniformly mixing black carbon powder with a weight percentage (wt %)>1% and a particle size<5 um and a silicone resin. Therefore, the light-emitting device 1′ may be applied to an adaptive driving beam.

As shown in FIG. 9, in some embodiments, the width w80S of the section 80S of the second encapsulating layer 80 may be less than or equal to the width w60S of the section 60S of the first encapsulating layer 60. As shown in FIG. 9, in some embodiments, the height h80S of the section 80S of the second encapsulating layer 80 located in the wavelength conversion portion 72 may be equal to the height h72S of the wavelength conversion portion 72. As shown in FIG. 9, in some embodiments, the width of the reflective layer 34 is constant in the first direction D1.

In the following, the same or similar reference numerals and descriptions are omitted.

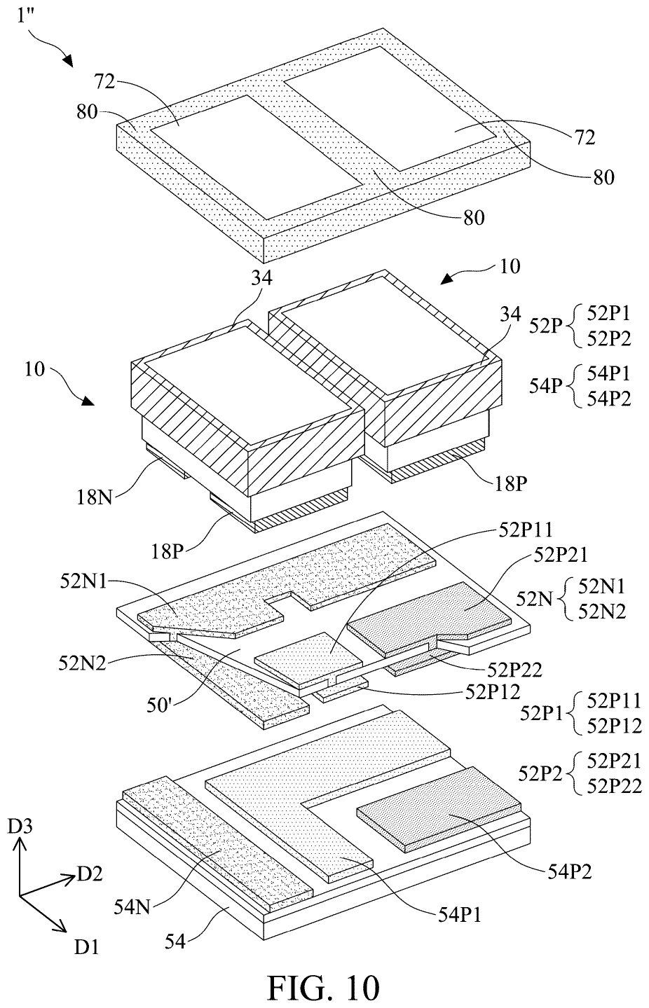

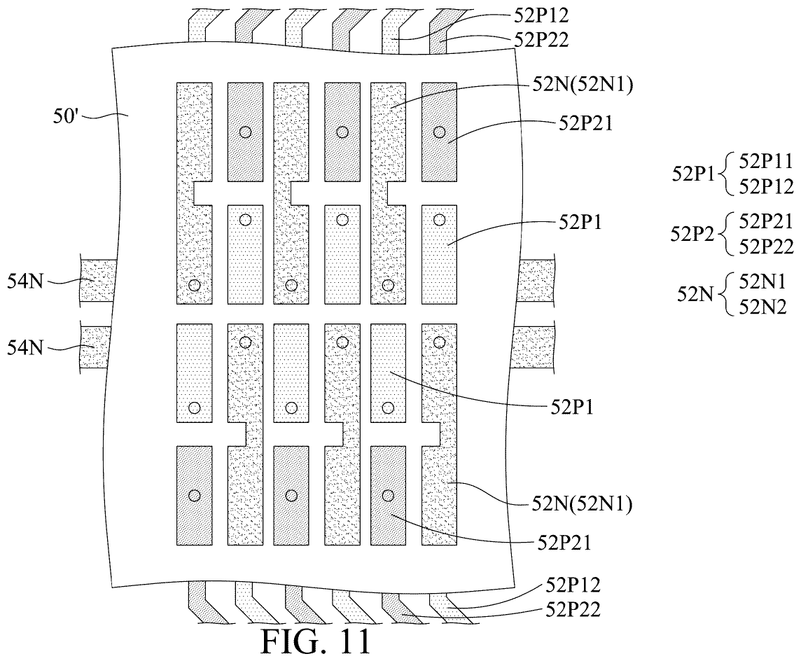

Referring to FIG. 10, it is a three-dimensional exploded view of the light-emitting device 1″ of the present disclosure according to some embodiments. For ease of explanation, FIG. 10 may show the light-emitting element 10, the reflective layer 34, the substrate 50′, and the circuit board 54. For ease of explanation, FIG. 10 may show that two light-emitting elements 10 are electrically connected to the circuit board 54, but the present disclosure is not limited thereto. In some embodiments, the substrate 50′ may be the same as or different from the substrate 50. In some embodiments, the substrate 50 may include the substrate 50′ and the circuit board 54, or the substrate 50 may function as both the substrate 50′ and the circuit board 54.

In some embodiments, the substrate 50′ may include the third contact pad 52P (including third contact pads 52P1 and 52P2) and the fourth contact pad 52N that are electrically isolated from each other. In some embodiments, the circuit board 54 may include a fifth contact pad 54P (including fifth contact pads 54P1 and 54P2) and a sixth contact pad 54N that are electrically isolated from each other. In some embodiments, the first contact pads 18P of the two light-emitting elements 10 may be electrically connected to the third contact pad 52P1 and the third contact pad 52P2 of the substrate 50′, respectively, and the second contact pads 18N of the two light-emitting elements 10 may be electrically connected to the fourth contact pad 52N of the substrate 50′. The third contact pad 52P1 may be electrically connected to the fifth contact pad 54P1, the third contact pad 52P2 may be electrically connected to the fifth contact pad 54P2, and the fourth contact pad 52N may be electrically connected to the sixth contact pad 54N. Accordingly, each light-emitting element 10 may be controlled independently by the circuit board 54 to avoid the problem that the all light-emitting elements 10 need to emit light at the same time. Therefore, each light-emitting element 10 may emit light according to requirements. Therefore, the light-emitting device 1″ of the present disclosure may be applied to an adaptive driving beam.

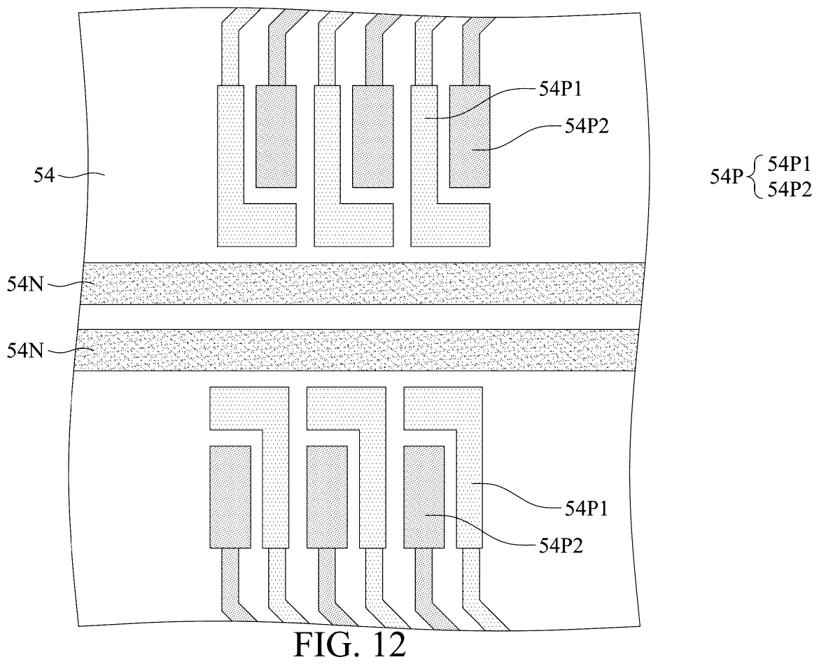

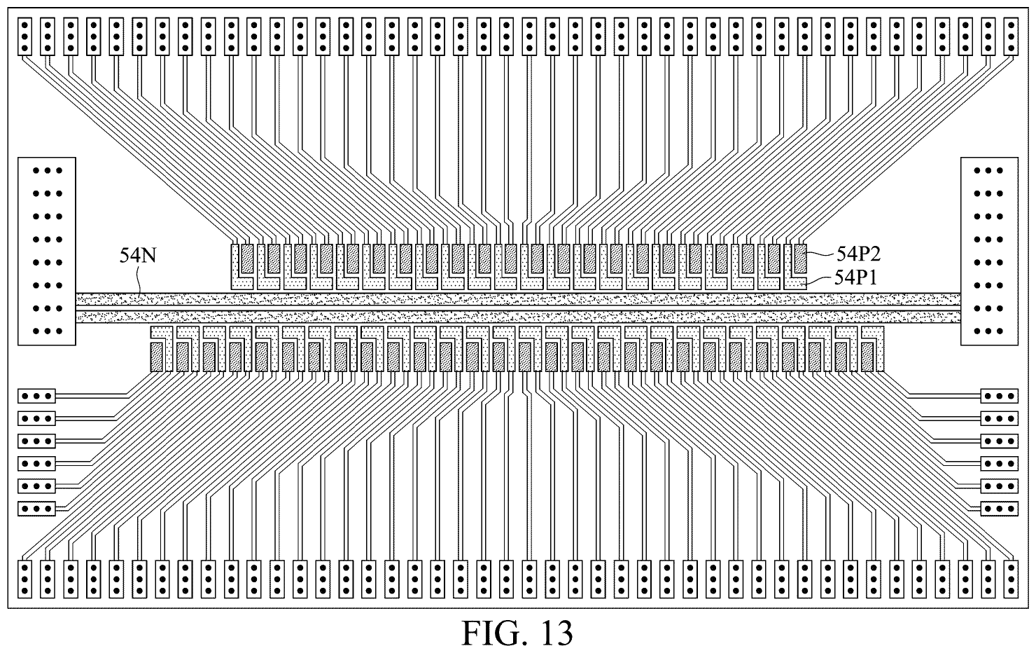

Referring to FIG. 11, it is a partial top view of a portion of the circuit board 54 and the substrate 50′ of the present disclosure according to some embodiments. Referring to FIG. 12, it is a partial top view of the circuit board 54 of the present disclosure according to some embodiments. Referring to FIG. 13, it is a top view of the circuit board 54 of the present disclosure according to some embodiments. For convenience of explanation, some elements may be omitted in FIGS. 11 to 13.

In some embodiments, in detail, in order to accommodate more light-emitting elements 10 to form an array of light-emitting elements 10, the fourth contact pad 52N may include a fourth contact pad 52N1 and a fourth contact pad 52N2. As shown in FIG. 10, in some embodiments, the fourth contact pad 52N1 may extend longitudinally (for example, along the second direction D2 in FIG. 10) above the substrate 50′ and the fourth contact pad 52N1 may be (electrically) connected to the corresponding pair of the light-emitting elements 10. As shown in FIG. 10, in some embodiments, the fourth contact pad 52N2 may extend laterally (for example, along the first direction D1 in FIG. 10) below the substrate 50′ to connect all fourth contact pad 52N1 of the laterally expanded light-emitting element array together and the fourth contact pad 52N2 may be (electrically) connected to the sixth contact pad 54N of the circuit board 54.

As shown in FIG. 10, in some embodiments, the third contact pad 52P1 may include a third contact pad 52P11 located above the substrate 50′ and a third contact pad 52P12 located below the substrate 50′. As shown in FIG. 10, in some embodiments, the third contact pad 52P2 may include a third contact pad 52P21 located above the substrate 50′ and a third contact pad 52P22 located below the substrate 50′. In some embodiments, the third contact pads 52P11 and 52P21 may be (electrically) connected to the corresponding pair of light-emitting elements 10, respectively. In some embodiments, the third contact pad 52P12 and the third contact pad 52P22 may be (electrically) connected to the corresponding fifth contact pad 54P1 and the corresponding fifth contact pad 54P2, respectively. As shown in FIG. 10, in some embodiments, at least one sixth contact pad 54N may extend along the lateral direction of the circuit board 54 (for example, along the first direction D1 in FIG. 10), and the fifth contact pads 54P1 and 54P2 may extend along the longitudinal direction of the circuit board 54 (for example, along the second direction D2 in FIG. 10).

As shown in FIGS. 10 to 13, the substrate 50′ utilizes the design of via holes to connect the second contact pads 18N of the multiple light-emitting elements 10 together by the corresponding fourth contact pad 52N extending laterally below the substrate 50′, in order to (electrically) connect to the sixth contact pad 54N of the circuit board 54. Correspondingly, the first contact pads 18P of the multiple light-emitting elements 10 are respectively connected to the corresponding third contact pads 52P1 and 52P2 extending longitudinally below the substrate 50′ and are respectively (electrically) connected to the fifth contact pad 54P1 and the fifth contact pad 54P2 of the circuit board 54. However, the present disclosure is not limited thereto.

In other embodiments, the polarity of the contact pads of all the light-emitting elements may also be reversed, so that the first contact pads 18P of the multiple light-emitting elements 10 connect with each other, and the second contact pads 18N of the multiple light-emitting elements 10 connect the corresponding contact pads, respectively.

In some embodiments, by the fourth contact pad 52N and the third contact pad 52P of the substrate 50′ and the sixth contact pad 54N and the fifth contact pad 54P of the circuit board 54, the horizontal/vertical circuit may be extended outward as shown in FIG. 13. Furthermore, in an array of light-emitting elements 10 formed by a plurality of light-emitting elements 10, each light-emitting element 10 may be independently controlled.

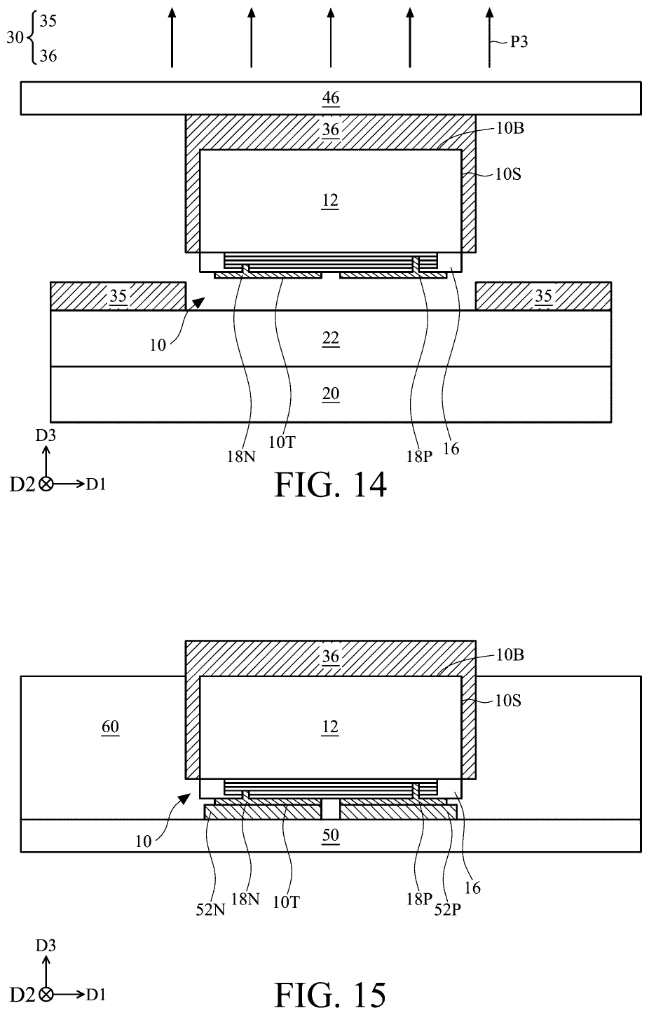

Referring to FIG. 14, it is a schematic cross-sectional view showing various stages of the manufacturing method of the light-emitting device 1 of the present disclosure according to some embodiments. FIG. 14 may continue from FIG. 2. In some embodiments, as shown in FIG. 14, a third removal process P3 may be performed to remove a third portion 35 of the reflective layer 30 so as to form the reflective layer 36. In some embodiments, a fourth adhesive layer 46 may be formed on the reflective layer 30 so that the reflective layer 30 is between the light-emitting element 10 and the fourth adhesive layer 46. Then, the first adhesive layer 22 may be separated to remove the first adhesive layer 22 and the third portion 35 of the reflective layer 30, to expose the top surface 10T of the light-emitting element 10. In some embodiments, the fourth adhesive layer 46 may be disposed directly on the top surface of the reflective layer 30. In some embodiments, the material and formation method of the fourth adhesive layer 46 may be the same as or different from the material and formation method of the first adhesive layer 22. In some embodiments, the viscosity of the fourth adhesive layer 46 may be greater than the viscosity of the first adhesive layer 22. Therefore, during the third removal process P3, the light-emitting element 10 is bonded to the fourth adhesive layer 46 and separated from the first adhesive layer 22 and the carrier board 20. In some embodiments, the third portion 35 may be a portion of the reflective layer 30 located on the first adhesive layer 22.

Referring to FIG. 15, it is a schematic cross-sectional view showing various stages of the manufacturing method of the light-emitting device 1 of the present disclosure according to some embodiments. As shown in FIG. 15, in some embodiments, the light- emitting element 10 is transferred to the substrate 50. Then, the first encapsulating layer 60 may be formed on the substrate 50. In some embodiments, the top surface of the first encapsulating layer 60 may be aligned with the bottom surface 10B of the light-emitting element 10. Accordingly, the first encapsulating layer 60 may function as a stop layer and function as a reference for subsequent removal of the reflective layer 36.

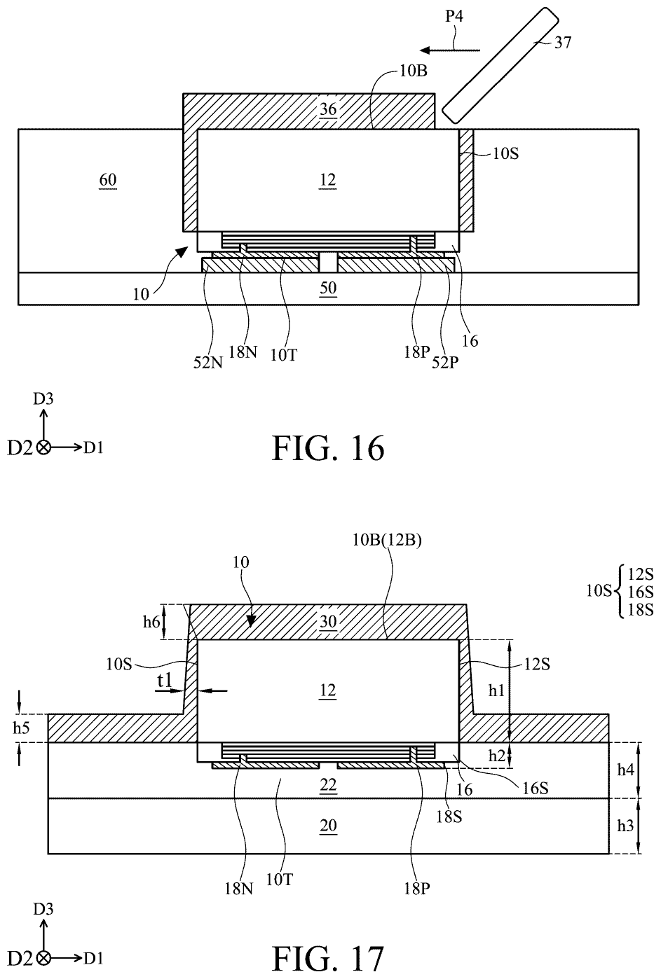

Referring to FIG. 16, it is a schematic cross-sectional view showing various stages of the manufacturing method of the light-emitting device 1 of the present disclosure according to some embodiments. In some embodiments, as shown in FIG. 16, a fourth removal process P4 may be performed to form the reflective layer 34. In some embodiments, after performing the fourth removal process P4, the top surface of the reflective layer 36 and the top surface of the first encapsulating layer 60 may be coplanar, and the bottom surface 10B of the light-emitting element 10 is exposed. In some embodiments, the fourth removal process P4 may be performed by a scraper 37. For example, the scraper 37 may be an acrylic resin scraper or a fiberglass scraper (for example, an FR4 scraper). In some embodiments, the fourth removal process P4 may remove the reflective layer 36 on the bottom surface 10B of the light-emitting element 10.

In some embodiments, the process shown in FIG. 7 may be subsequently performed to form the light-emitting device 1. In some embodiments, the processes shown in FIGS. 7 to 9 may be subsequently performed to form the light-emitting device 1′. In other embodiments, the processes shown in FIGS. 7 to 10 may be subsequently performed to form the light-emitting device 1″. In some embodiments, after performing the process shown in FIG. 6, a fourth removal process P4 shown in FIG. 16 may be further performed to expose the bottom surface 10B of the light-emitting element 10. Next, the light-emitting device 1 in FIG. 7 may be formed. Alternatively, the processes shown in FIGS. 8 and 9 may be subsequently performed to form the light-emitting device 1′. In other words, after performing the first removal process P1 and the second removal process P2, the fourth removal process P4 may be further performed to further ensure that no material of the reflective layer remains on the bottom surface 10B of the light-emitting element 10.

Referring to FIGS. 17 to 19, they are schematic cross-sectional views of various stages of the manufacturing method of the light-emitting device 2 of the present disclosure according to some embodiments.

As shown in FIG. 17, in some embodiments, the thickness t1 of the reflective layer 30 on the side surface 12S of the base layer 12 becomes thinner as it approaches the bottom surface 12B of the base layer 12. The thickness t1 of the reflective layer 30 on the side surface 12S of the base layer 12 becomes thicker as it approaches the top surface 12T of the base layer 12. For example, the thickness t1 of the reflective layer 30 close to the top surface 12T of the base layer 12 may be 0.5 um, and the thickness t1 of the reflective layer 30 close to the bottom surface 12B of the base layer 12 may be 0.2 um. In some embodiments, the thickness t1 of the reflective layer 30 on the side surface 12S of the base layer 12 gradually becomes thinner from close to the top surface 12T of the base layer 12 to close to the bottom surface 12B of the base layer 12.

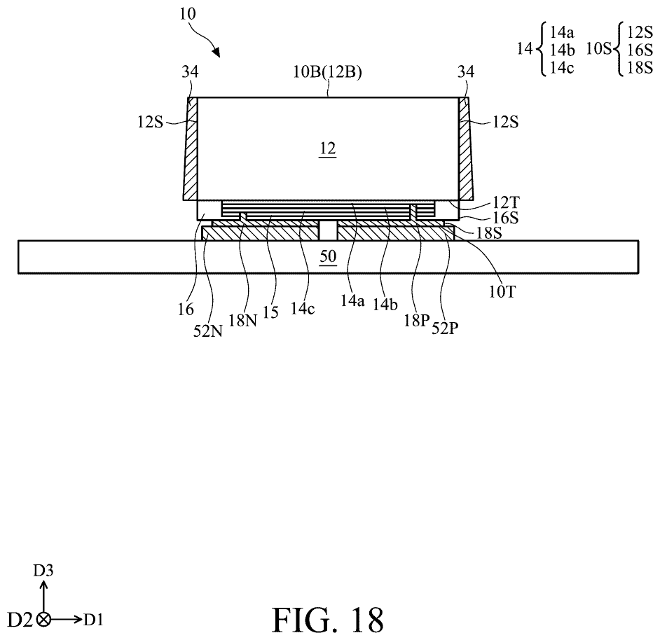

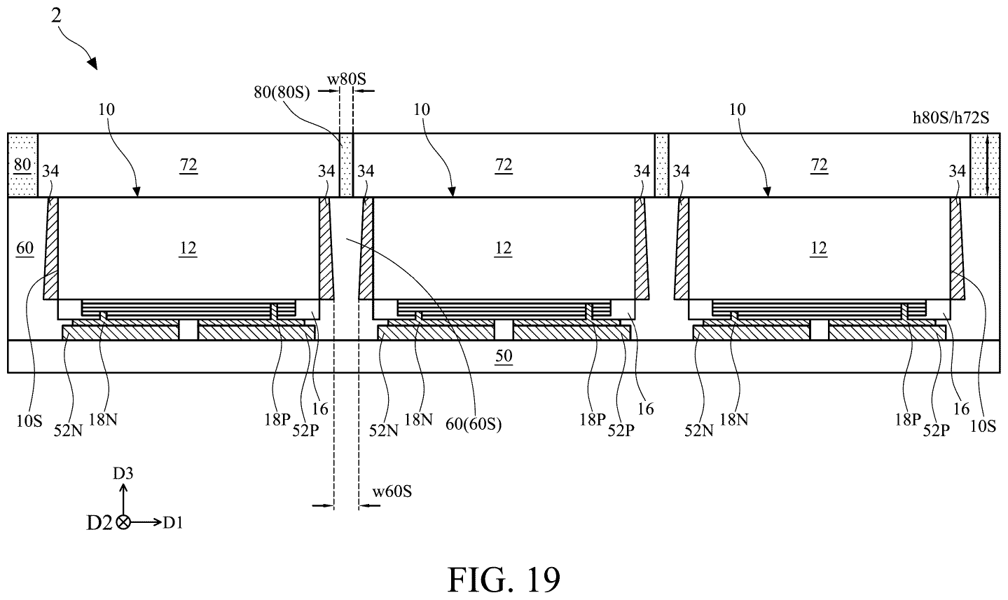

In some embodiments, the structure shown in FIG. 17 may then perform processes similar to those shown in FIGS. 3 and 4 to form the structure shown in FIG. 18, and then perform processes similar to those shown in FIGS. 6 to 7 to form the light-emitting device 1 shown in FIG. 7. The thickness t1 of the reflective layer 30 on the side surface 12S of the base layer 12 of the light-emitting device 1 gradually becomes thinner from close to the top surface 12T of the base layer 12 to close to the bottom surface 12B of the base layer 12. Alternatively, processes similar to those shown in FIGS. 8 and 9 may be subsequently performed to form the light-emitting device 2 shown in FIG. 19. In other embodiments, the structure shown in FIG. 17 may subsequently perform processes similar to those shown in FIGS. 14 to 16, and then perform a process similar to that shown in FIG. 7 to form the light-emitting device 1 shown in FIG. 7. The thickness t1 of the reflective layer 30 on the side surface 12S of the base layer 12 of the light-emitting device 1 gradually becomes thinner from close the top surface 12T of the base layer 12 to close to the bottom surface 12B of the base layer 12. Alternatively, processes similar those shown in FIGS. 8 and 9 may be subsequently performed to form the light-emitting device 2 shown in FIG. 19. As shown in FIG. 19, in some embodiment, the width of the reflective layer 34 may decrease away from the substrate 50 in the first direction D1.

Referring to FIGS. 20 to 22, they are schematic cross-sectional views showing various stages of the manufacturing method of the light-emitting device 3 of the present disclosure according to some embodiments.

As shown in FIG. 20, in some embodiments, the adhesive layer 24 may be formed on the side surface 10S and the bottom surface 10B of the light-emitting element 10. In some embodiments, the adhesive layer 24 is formed on the side surface 12S of the base layer 12 and the bottom surface 12B of the base layer 12. Then, the reflective layer 30 is formed on the adhesive layer 24, and a barrier layer 26 is formed on the reflective layer 30. In some embodiments, the material of the adhesive layer 24 may include chromium (Cr), titanium (Ti), alloys thereof, the like, or a combination thereof, but the present disclosure is not limited thereto. In some embodiments, the material of the barrier layer 26 may include titanium tungsten (TiW), platinum (Pt), titanium (Ti), gold (Au), alloys thereof, the like, or a combination thereof, but the present disclosure is not limited thereto. Accordingly, the material of barrier layer 26 may prevent oxidation, sulfidation, and other forms of degradation of the reflective layer 30. Furthermore, the material of the barrier layer 26 may increase the moisture resistance of the reflective layer 30.

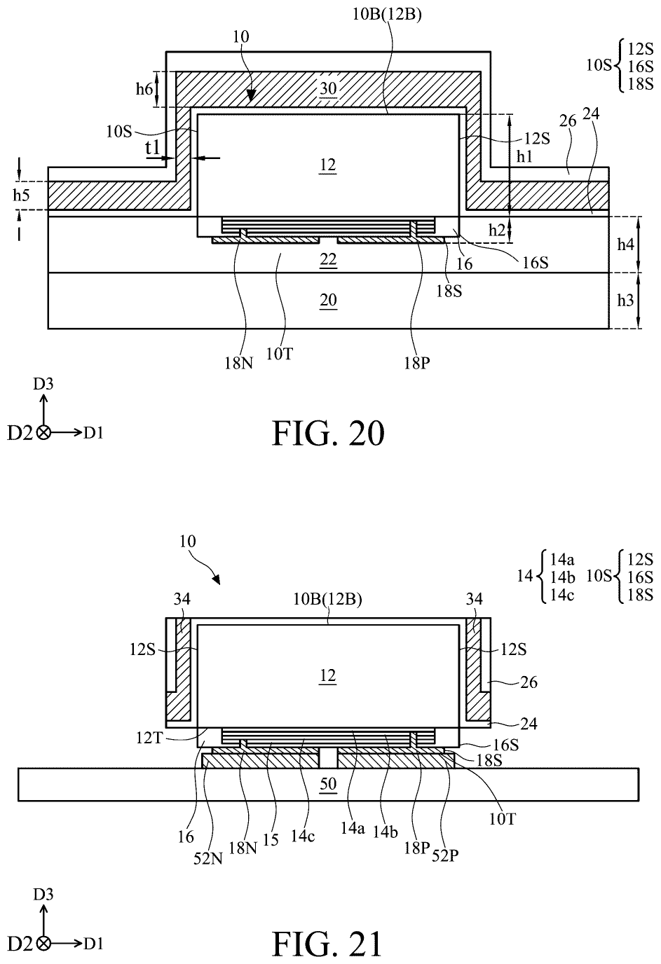

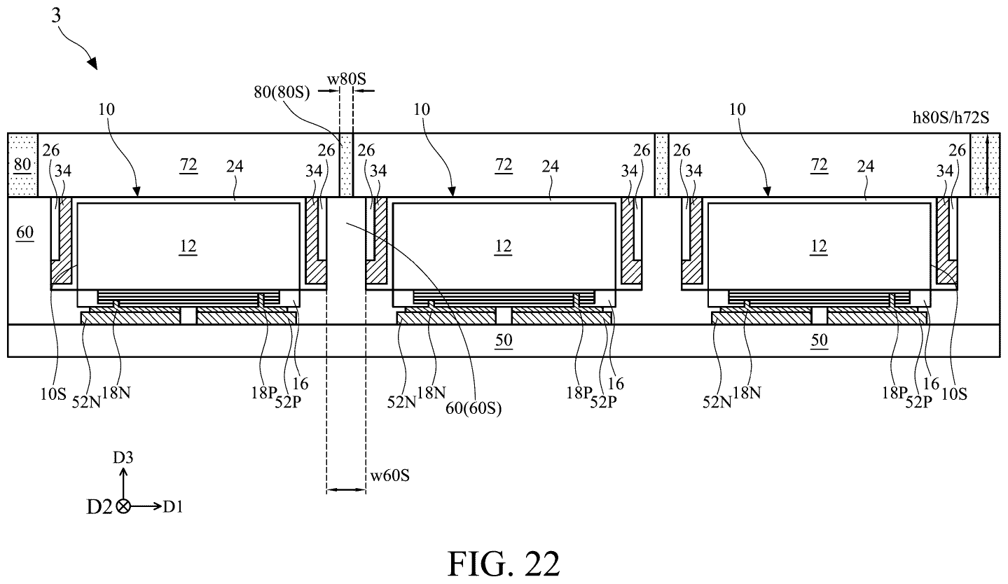

In some embodiments, the structure shown in FIG. 20 may then perform processes similar to those shown in FIGS. 3 and 4 to form the structure shown in FIG. 21, and then performing processes similar to those shown in FIGS. 6 to 7 to form the light-emitting device 1 shown in FIG. 7. The adhesive layer 24, the reflective layer 30, and the barrier layer 26 are provided on the side surface 12S of the base layer 12 of the light-emitting device 1. Alternatively, processes similar to those shown in FIGS. 8 and 9 may be subsequently performed to form the light-emitting device 3 shown in FIG. 22. In other embodiments, the structure shown in FIG. 20 may subsequently perform processes similar to those shown in FIGS. 14 to 16, and then perform processes similar to those shown in FIGS. 7 to 9 to form the light-emitting device 3 shown in FIG. 22. As shown in FIG. 22, in some embodiments, the barrier layer 26 is disposed between the reflective layer 34 and the first encapsulating layer 60 and between the reflective layer 34 and the wavelength conversion portion 72. The barrier layer 26 exposes a portion of a side surface of the reflective layer 34. As shown in FIG. 22, in some embodiments, the adhesive layer 24 is disposed between the light-emitting element 10 and the reflective layer 34. The reflective layer 34 is disposed between the adhesive layer 24 and the barrier layer 26.

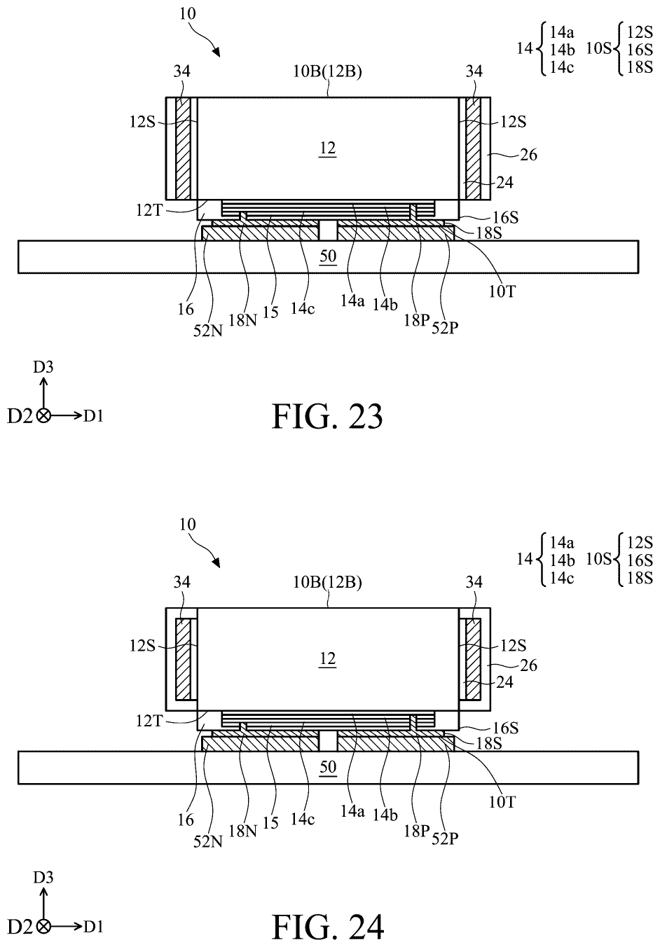

Referring to FIG. 23, it is a schematic cross-sectional view showing various stages of the manufacturing method of the light-emitting device of the present disclosure according to some embodiments. As shown in FIG. 23 (similar to FIG. 21), in some embodiments, the barrier layer 26 may completely cover the side surfaces of the reflective layer 34. In some embodiments, the barrier layer 26 may cover the side surfaces of the reflective layer 34. In some embodiments, the reflective layer 34 may be interposed between the adhesive layer 24 and the barrier layer 26 such that the adhesive layer 24 and the barrier layer 26 respectively completely cover the opposite side surfaces of the reflective layer 34 and only expose the top surface and bottom surface of the reflective layer 34. Accordingly, the material of the barrier layer 26 may prevent oxidation, sulfidation, and other forms of degradation of the reflective layer 30. Furthermore, the material of the barrier layer 26 may increase the moisture resistance of the reflective layer 30.

Referring to FIG. 24, it is a schematic cross-sectional view showing various stages of the manufacturing method of the light-emitting device of the present disclosure according to some embodiments. As shown in FIG. 24 (similar to FIG. 21), in some embodiments, the barrier layer 26 may completely cover the top, side, and bottom surfaces of the reflective layer 34 without exposing the reflective layer 34. In some embodiments, the barrier layer 26 may cover the top, side, and bottom surfaces of the reflective layer 34 without exposing the reflective layer 34. In some embodiments, the barrier layer 26 may cover the top and bottom surfaces of the adhesive layer 24 and the top, side, and bottom surfaces of the reflective layer 34. Accordingly, the material of the barrier layer 26 may prevent oxidation, sulfidation, and other forms of degradation of the reflective layer 30. Furthermore, the material of the barrier layer 26 may increase the moisture resistance of the reflective layer 30. In some embodiments, the barrier layer 26 and the adhesive layer 24 may completely surround the reflective layer 34.

Referring to FIG. 25, it is a schematic cross-sectional view showing various stages of the manufacturing method of the light-emitting device 4 of the present disclosure according to some embodiments. FIG. 25 may continue from FIG. 5. In some embodiments, as shown in FIG. 25, a protective layer 38 may be formed on the light-emitting element 10 and the reflective layer 34 to protect the light-emitting element 10 and the reflective layer 34 from damage. For example, the protective layer 38 may prevent the light-emitting element 10 and the reflective layer 34 from being damaged by external force, moisture, oxygen, reactive gas, and the like. In some embodiments, when the reflective layer 34 may include silver (Ag), the protective layer 38 may avoid the problem of reducing the reflectivity of the sulfidation of reflective layer 34 including silver. In some embodiments, the protective layer 38 may include silicon dioxide (SiO₂), titanium dioxide (TiO₂), tantalum pentoxide (Ta₂O₅), aluminum oxide (Al₂O₃), the like, or a combination thereof, but the present disclosure is not limited thereto. In some embodiments, the protective layer 38 may be formed by plasma chemical vapor deposition (PECVD), electron beam (E-gun) evaporation, or atomic layer deposition (ALD). In some embodiments, the protective layer 38 may include epoxy resin or silicone resin. In some embodiments, the protective layer 38 may be formed by spray or spin coating.

Referring to FIG. 26, it is a schematic cross-sectional view showing various stages of the manufacturing method of the light-emitting device 4 of the present disclosure according to some embodiments. In some embodiments, the processes shown in FIGS. 6 and 7 may be performed to form the light-emitting device 1 shown in FIG. 7. The light-emitting device 1 has the protective layer 38. Alternatively, the processes shown in FIGS. 8 and 9 may be subsequently performed to form the light-emitting device 4. In some embodiments, in the first direction D1, the protective layer 38 may be located between the reflective layer 34 and the first encapsulating layer 60. In some embodiments, in the third direction D3, the protective layer 38 may be located between the light-emitting element 10 and the wavelength conversion portion 72.

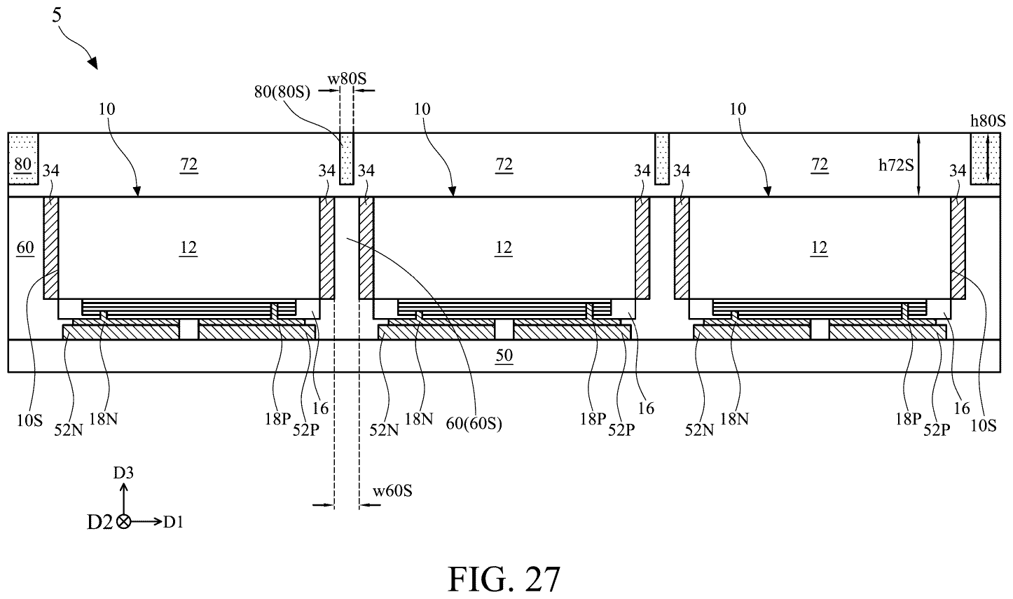

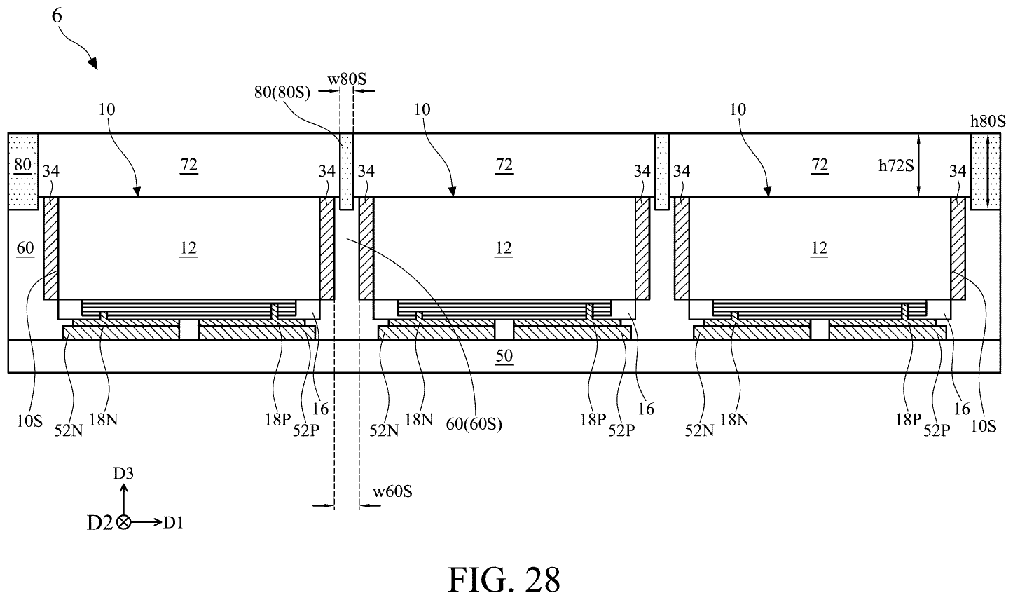

Referring to FIGS. 27 and 28, they are respectively schematic cross-sectional views of the light-emitting devices 5 and 6 of the present disclosure according to some embodiments.

As shown in FIG. 27, in some embodiments, in the light-emitting device 5, since the cutting depth of the cutting process may be less than the height of the wavelength conversion layer 70 (not shown), the height h80S of the section 80S of the second encapsulating layer 80 located in the wavelength conversion portion 72 may be less than the height h72S of the wavelength conversion portion 72.

As shown in FIG. 28, in some embodiments, in the light-emitting device 6, since the cutting depth of the cutting process may be greater than the height of the wavelength conversion layer 70 (not shown), the height h80S of the section 80S of the second encapsulating layer 80 located in the wavelength conversion portion 72 may be greater than the height h72S of the wavelength conversion portion 72. That is, the second encapsulating layer 80 may extend between the base layers 12 of the two light-emitting elements 10.

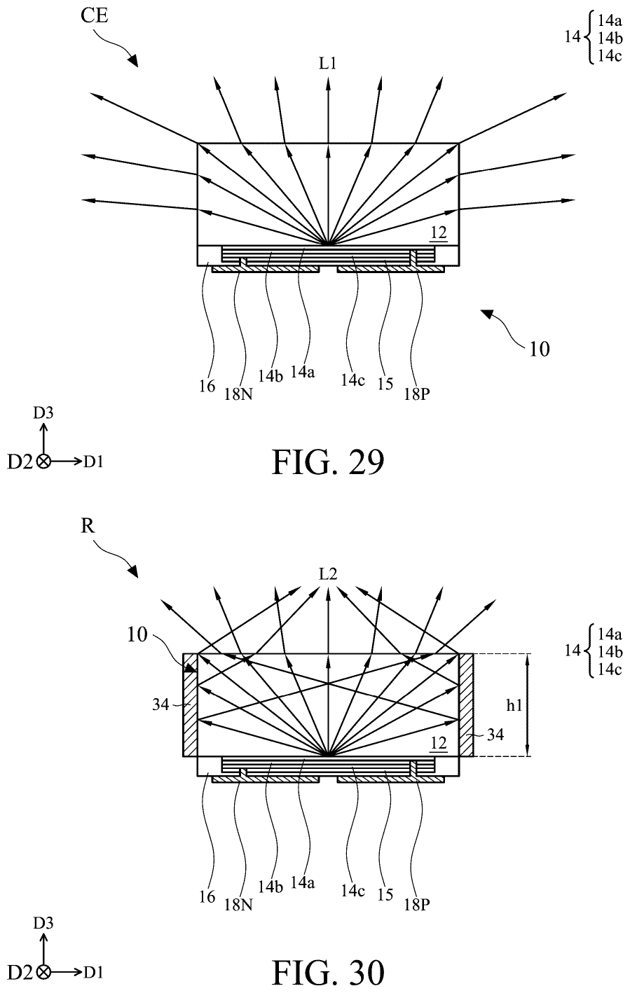

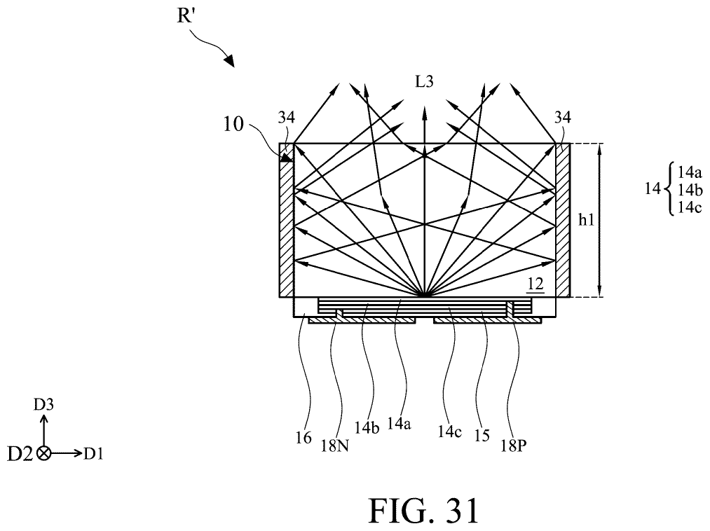

Referring to FIGS. 29, 30 and 31, they respectively show schematic diagrams of optical paths of a comparative example of the light-emitting device of the present disclosure (a portion CE of the comparative example of the light-emitting device), a portion R of the light-emitting device 1, and a portion R′ of the light-emitting device 1. The portion R′ of the light-emitting device 1 may replace the portion R of the light-emitting device 1. For convenience of explanation, the light-emitting element 10 and the reflective layer 34 are shown, and other elements are omitted. The portion CE of the comparative example of the light-emitting device does not include the reflective layer 34, and the portion R of the light-emitting device 1 and the portion R′ of the light-emitting device 1 each include the reflective layer 34. The first height h1 of the base layer 12 of the portion R of the light-emitting device 1 is smaller than the first height hl of the base layer 12 of the portion R′ of the light-emitting device 1. As shown in FIG. 29, in the comparative example, the light L1 is dispersed, causing light leakage and cross-talk. As shown in FIGS. 30 and 31, in the portion R of the light-emitting device 1 and the portion R′ of the light-emitting device 1, the light L2 and the light L3 are emitted toward the third direction D3, thereby increasing the front luminous amount and/or brightness of the light-emitting device, avoiding the light leakage and/or cross-talk. In some embodiments, when the first height h1 of the base layer 12 is larger, the light-emitting angle shown by the light L3 is smaller, and the front luminous amount and/or brightness is stronger.

In some embodiments, any one or more of the light-emitting devices 1, 1′, 1″, and 2˜6 may be arbitrarily combined with each other. In some embodiments, any one or more of the light-emitting devices 1, 1′, 2˜6 may be used in combination with the substrate 50 and the circuit board 54 shown in FIG. 10.

In some embodiments, the light-emitting devices 1, 1′, 1″, and 2˜6 may be used in the headlight module of the vehicle. The headlight module is installed on the left and right sides of the front of the vehicle. The light-emitting elements 10 in the light-emitting devices 1, 1′, 1″, and 2˜6 may be controlled independently.

In summary, since the light-emitting device may include the reflective layer disposed on the side surface of the light-emitting element, the luminous efficiency of the light-emitting element may be improved. Therefore, the front luminous amount and/or brightness of the light-emitting device may be increased, and light leakage and/or cross-talk may be avoided.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting device, comprising:
a substrate;
a light-emitting element disposed on the substrate and having a side surface;
a reflective layer disposed on the side surface of the light-emitting element;
a first encapsulating layer disposed on the substrate, wherein the first encapsulating layer surrounds the light-emitting element and the reflective layer;
a wavelength conversion portion disposed on the light-emitting element; and
a second encapsulating layer disposed on the first encapsulating layer, wherein the second encapsulating layer surrounds the wavelength conversion portion.

2. The light-emitting device as claimed in claim 1, wherein the light-emitting element has a bottom surface, and the reflective layer exposes the bottom surface of the light-emitting element.

3. The light-emitting device as claimed in claim 1, wherein the light-emitting element comprises:
a base layer having a top surface, a bottom surface opposite to the top surface, and a side surface connecting the top surface and the bottom surface;
semiconductor stacked layers disposed on the top surface of the base layer;
an insulating layer disposed on the semiconductor stacked layers and the top surface of the base layer; and
a contact pad disposed on the insulating layer, wherein the contact pad passes through the insulating layer and is electrically connected to the semiconductor stacked layers,
wherein the reflective layer covers the side surface of the base layer of the light- emitting element.

4. The light-emitting device as claimed in claim 3, wherein the reflective layer exposes the insulating layer and the contact pad.

5. The light-emitting device as claimed in claim 1, further comprising:
a protective layer disposed on the light-emitting element and the reflective layer.

6. The light-emitting device as claimed in claim 5, wherein the protective layer is located between the reflective layer and the first encapsulating layer, and the protective layer is located between the light-emitting element and the wavelength conversion portion.

7. The light-emitting device as claimed in claim 1, wherein the reflective layer has a thickness greater than or equal to 0.2 um and less than or equal to 10 um.

8. The light-emitting device as claimed in claim 1, wherein the reflective layer comprises silver (Ag), aluminum (Al), copper (Cu), chromium (Cr), titanium (Ti), or a combination thereof.

9. The light-emitting device as claimed in claim 8, wherein the reflective layer comprises an aluminum-copper alloy (AlCu), and a weight of copper in the aluminum-copper alloy accounts for 0.1% to 20% of a total weight of the aluminum-copper alloy.

10. The light-emitting device as claimed in claim 1, wherein the first encapsulating layer comprises a first material.

11. The light-emitting device as claimed in claim 10, wherein the first material comprises a light-reflecting material, and the second encapsulating layer comprises a light-reflecting material or a light-absorbing material.

12. The light-emitting device as claimed in claim 1, wherein a width of the reflective layer is constant.

13. The light-emitting device as claimed in claim 1, wherein a width of the reflective layer decreases away from the substrate.

14. The light-emitting device as claimed in claim 1, further comprising:
a barrier layer disposed between the reflective layer and the first encapsulating layer, wherein the barrier layer comprises titanium tungsten (TiW), platinum (Pt), titanium (Ti), or gold (Au).

15. The light-emitting device as claimed in claim 14, wherein the barrier layer is disposed between the reflective layer and the wavelength conversion portion.

16. The light-emitting device as claimed in claim 14, wherein the barrier layer exposes a portion of a side surface of the reflective layer.

17. The light-emitting device as claimed in claim 14, wherein the barrier layer covers a side surface of the reflective layer.

18. The light-emitting device as claimed in claim 17, wherein the barrier layer covers a side surface, a top surface, and a bottom surface of the reflective layer.

19. The light-emitting device as claimed in claim 14, further comprising:
an adhesive layer, disposed between the light-emitting element and the reflective layer, wherein the reflective layer is disposed between the adhesive layer and the barrier layer.

20. The light-emitting device as claimed in claim 1, further comprising:
a protective layer disposed on the light-emitting element and the reflective layer wherein the protective layer comprises silicon dioxide (SiO₂), titanium dioxide (TiO₂), tantalum pentoxide (Ta₂O₅), or aluminum oxide (Al₂O₃).
